(19) United States
(12) Patent Application Publication
(10) Pub. No.: US 2018/0108654 A1
(43) Pub. Date: Apr. 19, 2018

(54) FINFET DEVICE WITH LOW RESISTANCE FINS

(71) Applicant: GLOBALFOUNDRIES, INC., Grand Cayman (KY)

(72) Inventors: Viorel C. ONTALUS, Unionville, CT (US); Arvind KUMAR, Chappaqua, NY (US); Xin WANG, Malta, NY (US); Gan WANG, Ballston Lake, NY (US)

(73) Assignee: GLOBALFOUNDRIES, INC., GRAND CAYMAN (KY)

(21) Appl. No.: 15/293,461

(22) Filed: Oct. 14, 2016

(51) Int. Cl. H01L 27/088; H01L 29/78; H01L 29/08; H01L 21/8234

(52) U.S. Cl. CPC H01L 27/0886; H01L 29/785; H01L 21/823418; H01L 21/823431; H01L 29/0847

(57) ABSTRACT

A method of forming a FinFET device includes ion implanting a diffusion-inhibiting species such as carbon into source and drain regions of a semiconductor fin prior to a dopant activating anneal. The implanted carbon, which can be incorporated into the fin in conjunction with a replacement metal gate process after defining a sacrificial gate but prior to forming sidewall spacers on the gate, forms a barrier that impedes dopant diffusion across the barrier, which enables abrupt junctions and higher overall dopant concentrations within the semiconductor fin.

### BACKGROUND

The present application relates generally to semiconductor devices, and more particularly to fin field effect transistors (FinFETs) and their methods of fabrication.

Fully-depleted devices such as fin field effect transistors are candidates to enable scaling of next generation gate lengths to 14 nm and below. Fin field effect transistors present a three-dimensional architecture where the transistor channel is raised above the surface of a semiconductor substrate, rather than locating the channel at or just below the surface. With a raised channel, the gate can be wrapped around the sides of the channel, which provides improved electrostatic control of the device.

The manufacture of FinFETs typically leverages a self-aligned process to produce extremely thin fins, e.g., 20 nm wide or less, on the surface of a substrate using selective-etching techniques. A gate structure is then deposited to contact multiple surfaces of each fin to form a multi-gate architecture. While the thin channel enables robust control of the device, its shape limits the flow of current when the device is turned on. Thus, multiple fins are typically arranged in parallel to provide higher drive strength.

Furthermore, as FinFETs are scaled to advanced nodes, electrical interaction between the source and drain can interfere with the ability of the gate to control whether the device is on or off. This “short-channel effect” (SCE) phenomenon is exacerbated by doping of the fins to form source and drain regions adjacent to the channel.

The dopant concentration and attendant fin conductivity that is achievable by conventional methods such as diffusion from epitaxial layers is limited by dopant solubility and epitaxial growth kinetics, particularly at higher doping levels. Thus, additional doping (e.g., using ion implantation) is typically used to decrease resistance. However, higher dopant levels and related dopant diffusion contribute adversely to SCE degradation.

Accordingly, it would be advantageous to provide a method to form highly-doped, low resistance fins without such high doping levels adversely affecting device performance and reliability.

### SUMMARY

In accordance with various embodiments of the present application, carbon implantation is used in conjunction with diffusion from epitaxy and/or dopant implantation into source/drain junctions to limit dopant diffusion and minimize SCE degradation. Implanted carbon forms a diffusion barrier within the fins that can produce a larger gradient in the dopant concentration at each of the source-channel and drain-channel junctions compared to fins not implanted with carbon. The implanted carbon barrier layer enables a higher overall dopant concentration within the source and drain regions of the fins while minimizing the diffusion of dopants from the source/drain regions into the channel region of the device. In various embodiments, carbon implantation may be performed prior to a dopant-diffusing anneal. In exemplary embodiments, carbon is implanted into source/drain regions of the fins in conjunction with a replacement metal gate process after forming a sacrificial gate but prior to forming sidewall spacers.

A method of forming a fin field effect transistor (FinFET) device includes forming a plurality of fins on a semiconductor substrate, and forming a sacrificial gate stack on portions of the fins. The sacrificial gate stack defines source/drain regions that are not covered by the sacrificial gate stack, and which are implanted with a diffusion-inhibiting species such as carbon or nitrogen. Source/drain junctions are then formed within the source/drain regions such as by ion implantation and/or diffusion from epitaxy.

A fin field effect transistor (FinFET) device includes a plurality of fins on a semiconductor substrate, a gate stack overlying portions of the fins, and at least one spacer on sidewalls of the gate stack and disposed adjacent to source/drain regions of the fins. The fins include a diffusion-inhibiting species such as carbon or nitrogen, which is located adjacent to a channel region of the fins, such as beneath the at least one spacer.

### BRIEF DESCRIPTION OF SEVERAL VIEWS OF THE DRAWINGS

The following detailed description of specific embodiments of the present application can be best understood when read in conjunction with the following drawings, where like structure is indicated with like reference numerals and in which:

FIG. 1 is a simplified schematic diagram of an example fin field effect transistor according to various embodiments;

FIG. 2 is a cross-sectional view showing a semiconductor substrate architecture used to fabricate a FinFET device according to various embodiments;

FIG. 3 is a cross-sectional view of the structure of FIG. 2 after etching a portion of the architecture to form a semiconductor fin;

FIG. 4A is a top-down plan view showing the formation of a sacrificial gate structure over a semiconductor fin;

FIG. 4B is a cross-sectional view along line B-B′ of the structure of FIG. 4A;

FIG. 5A is a top-down plan view showing the formation of a sidewall spacer on the sacrificial gate of FIG. 4A;

FIG. 5B is a cross-sectional view along line B-B′ of the structure of FIG. 5A;

FIG. 6 is a cross-sectional view of the FinFET of FIG. 1 showing raised active regions formed over source/drain regions of the semiconductor fins;

FIG. 7 shows representative dopant profiles for a conventional graded junction and for an abrupt junction including a diffusion-inhibiting species;

FIG. 8A shows the implantation of a diffusion-inhibiting species into source/drain regions of a semiconductor fin prior to the formation of a sidewall spacer;

FIG. 8B shows the formation of a sidewall spacer on the sacrificial gate of FIG. 8A;

FIG. 8C shows the formation of raised active regions over source/drain regions of a semiconductor fin and the implantation of dopants into the source/drain regions;

FIG. 8D depicts the structure of FIG. 8C following an activation anneal;

FIG. 9 shows the implantation of a diffusion-inhibiting species into source/drain regions of a semiconductor fin after the formation of a sidewall spacer;

FIG. 10 shows the implantation of a diffusion-inhibiting species into source/drain regions of a semiconductor fin after the formation of raised active regions over the fin; and

FIG. 11 is a cross-sectional view showing the planarization of a dielectric layer on the device shown in FIGS. 5A and 5B.

### DETAILED DESCRIPTION

Reference will now be made in greater detail to various embodiments of the subject matter of the present application, some embodiments of which are illustrated in the accompanying drawings. The same reference numerals will be used throughout the drawings to refer to the same or similar parts.

Embodiments of the application relate generally to the manufacture of semiconductor devices, and more particularly to the manufacture of fin field effect transistors (FinFETs). Exemplary devices include fin field effect transistors having locally-doped fins that exhibit low resistivity over the source and drain regions thereof. According to various embodiments, source and drain regions are implanted with carbon, which inhibits or retards intrafin diffusion of dopants.

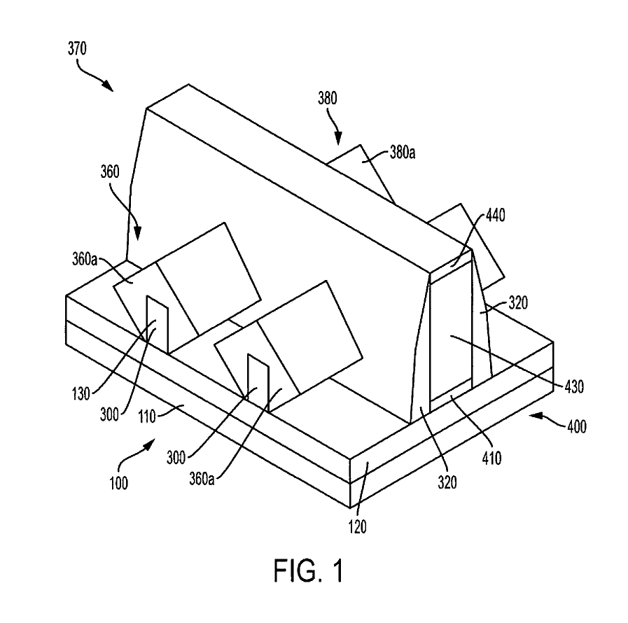

With reference to FIG. 1, a semiconductor device according to various embodiments includes a semiconductor substrate 100 having a plurality of semiconductor fins 300 formed thereon. Fins 300 include a source region 360 and a drain region 380 on opposing sides of gate structure 400, and a channel region 370 located between the source region 360 and the drain region 380 beneath the gate structure 400.

The semiconductor substrate 100 may be a semiconductor material such as silicon or a silicon-containing material, including a bulk substrate. Silicon-containing materials include, but are not limited to, single crystal Si, polycrystalline Si, single crystal silicon germanium (SiGe), polycrystalline silicon germanium, silicon doped with carbon (Si:C), amorphous Si, as well as combinations and multi-layers thereof. Example silicon substrates include silicon-on-insulator (SOI) substrates, silicon-on-sapphire (SOS) substrates, and the like. As used herein, the term “single crystal” denotes a crystalline solid in which the crystal lattice of the entire sample is substantially continuous and substantially unbroken to the edges of the sample with substantially no grain boundaries.

The semiconductor substrate 100 is not limited to silicon-containing materials, however, as the substrate 100 may comprise other semiconductor materials, including Ge and compound semiconductors such as GaAs, InAs and other like semiconductors. In various embodiments, semiconductor substrate 100 is a semiconductor-on-insulator (SOI) substrate and comprises, from bottom to top, a handle portion 110, an isolation layer 120, and a semiconductor material layer 130. Alternatively, semiconductor substrate may comprise a bulk semiconductor substrate.

Semiconductor substrate 100 may have dimensions as typically used in the art. In various embodiments, the substrate may be a semiconductor wafer. Example wafers diameters include, but are not limited to, 50, 100, 150, 200, 300 and 450 mm, including ranges between any of the foregoing values. The total substrate thickness may range from 250 microns to 1500 microns, although in particular embodiments the substrate thickness is in the range of 725 to 775 microns, which corresponds to thickness dimensions commonly used in silicon CMOS processing. The handle portion 110 may comprise (100)-oriented silicon or (111)-oriented silicon, for example.

The isolation layer 120 may comprise the buried oxide (BOX) layer of a semiconductor-on-insulator (SOI) substrate, or the oxidized layer of a bulk silicon substrate. The thickness of the isolation layer 120 may range from 30 to 300 nm, e.g., 30, 50, 100, 150, 200, 250 or 300 nm, including ranges between any of the foregoing values. The isolation layer 120 may comprise, for example, silicon dioxide (SiO₂). Alternatively, isolation layer 120 may comprise silicon nitride, silicon oxynitride, a low-k material, or any suitable combination of these materials.

Exemplary low-k materials include but are not limited to, amorphous carbon, fluorine-doped oxides, carbon-doped oxides, SiCOH or SiBCN. Commercially-available low-k dielectric products and materials include Dow Corning's SiLK™ and porous SiLK™, Applied Materials' Black Diamond™, Texas Instrument's Coral™ and TSMC's Black Diamond™ and Coral™. As used herein, a low-k material has a dielectric constant less than that of silicon dioxide. Disposed over the isolation layer 120 is a semiconductor material layer 130.

Semiconductor material layer 130 may comprise any of the semiconductor materials listed above in association with substrate 100. Example semiconductor materials that form semiconductor material layer 130, and which may be used for form semiconductor fins 300, include silicon (Si), germanium (Ge), silicon germanium (SiGe), III-V compound semiconductors such as GaAs, GaN, GaP, InAs, InSb, ZnSe, and ZnS, and II-VI compound semiconductors such as CdSe, CdS, CdTe, ZnSe, ZnS and ZnTe. For instance, semiconductor material layer 130 may include single crystal or polycrystalline silicon having a thickness ranging from 10 nm to 100 nm.

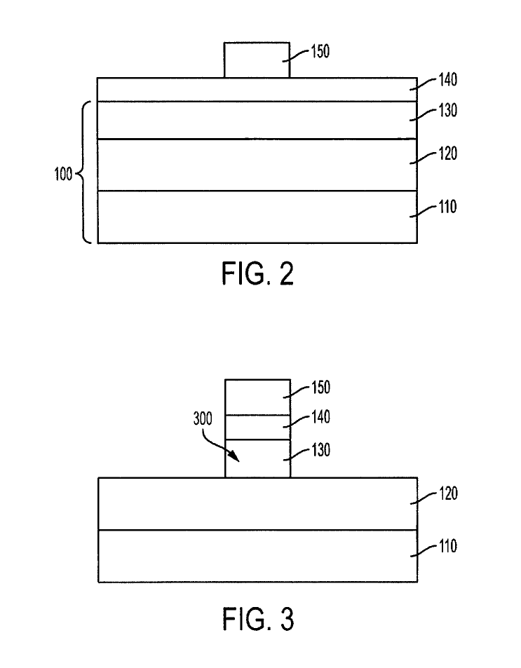

As shown in FIG. 2, at an intermediate stage of fabrication, a dielectric layer 140, such as silicon dioxide (e.g., SiO₂), silicon nitride (e.g., Si₃N₄), silicon oxynitride, or combinations thereof may be formed over semiconductor material layer 130 to serve as a protective cap during processing. In particular embodiments, the dielectric layer 140 includes a layer of silicon dioxide and an overlying layer of silicon nitride. For example, the dielectric layer 140 may include a layer of silicon dioxide disposed directly over the top surface of the semiconductor material layer 130, and a layer of silicon nitride disposed directly over the layer of silicon dioxide. Dielectric layer 140 may have a thickness ranging from 10 nm to 30 nm, for example.

In various embodiments, a plurality of fins 300 formed from the substrate 100 comprise a semiconductor material such as silicon, and may be formed from semiconductor material layer 130 by patterning and then etching the semiconductor material layer 130. The patterning process may comprise photolithography, which includes forming a layer of photoresist material 150 atop a material or material stack to be patterned. The photoresist material may include a positive-tone photoresist composition, a negative-tone photoresist composition, or a hybrid-tone photoresist composition. A layer of photoresist material 150 may be formed by a deposition process such as, for example, spin-on coating.

As shown in FIG. 3, the deposited photoresist 150 is subjected to a pattern of irradiation, and the exposed photoresist material is developed utilizing a conventional resist developer. In the instant embodiment, this provides a patterned layer of photoresist atop dielectric layer 140. The pattern provided by the patterned photoresist material is thereafter transferred into the underlying material layer or material layers (e.g., dielectric layer 140 and semiconductor material layer 130).

The pattern transfer etching process is typically an anisotropic etch. In embodiments, a dry etching process such as, for example, reactive ion etching can be used. In other embodiments, a wet chemical etchant can be used. In still further embodiments, a combination of dry etching and wet etching can be used. As shown in FIG. 3, the pattern transfer etching may stop on the isolation layer 120, or a portion of the isolation layer 120 may be removed during the formation of the fins 300. Alternatively, the pattern transfer etch may be stopped prior to reaching isolation layer 120 such that the fins extend upward from an un-etched portion of the semiconductor material layer 130 and thus have a fin height (H) that is less than the thickness of the semiconductor material layer 130.

In other embodiments, the patterning process may include a sidewall image transfer (SIT) process or a double patterning (DP) process. The SIT process includes forming a mandrel material layer (not shown) atop the material or material layers (i.e., crystalline silicon) that is to be patterned. The mandrel material layer can include any material (i.e., semiconducting, dielectric or conductive) that can be selectively removed from the structure during a subsequently performed etching process. For instance, the mandrel material layer may be composed of a dielectric such as, for example, Si₃N₄, a polyimide, or SiO₂. The mandrel material layer can be formed, for example, by chemical vapor deposition or plasma enhanced chemical vapor deposition. Following deposition of the mandrel material layer, the mandrel material layer can be patterned by lithography and etching to form a plurality of mandrel structures (also not shown) on the topmost surface of the semiconductor substrate.

The SIT process continues by forming a dielectric spacer on each sidewall of each mandrel structure. The dielectric spacer can be formed by deposition of a dielectric spacer material and then etching the deposited dielectric spacer material. The dielectric spacer material may comprise any dielectric spacer material such as, for example, silicon dioxide, silicon nitride or a dielectric metal oxide. Examples of deposition processes that can be used to provide the dielectric spacer material include, for example, chemical vapor deposition (CVD), plasma enhanced chemical vapor deposition (PECVD), or atomic layer deposition (ALD). Examples of etching that can be used to form the dielectric spacers include any etching process such as, for example, reactive ion etching.

After formation of the dielectric spacers, the SIT process continues by removing each mandrel structure. Each mandrel structure can be removed by an etching process that is selective for removing the mandrel material. Following the mandrel structure removal, the pattern provided by the dielectric spacers is transferred into the underlying material or material layers, e.g., semiconductor material layer 130. The pattern transfer may be achieved by at least one etching process. Examples of etching processes that can be used to transfer the pattern may include dry etching (i.e., reactive ion etching, plasma etching, and ion beam etching or laser ablation) and/or a chemical wet etch process. In one example, the etch process used to transfer the pattern may include one or more reactive ion etching steps. Upon completion of the pattern transfer, the SIT process concludes by removing the dielectric spacers from the structure. Each dielectric spacer may be removed by etching or a planarization process to reveal semiconductor fins.

As used herein, a “fin” refers to a contiguous semiconductor material that includes a pair of vertical sidewalls that are parallel to each other. As used herein, a surface is “vertical” if there exists a vertical plane from which the surface does not deviate by more than three times the root mean square roughness of the surface. Each of a plurality of fins 300 can comprise a single crystal semiconductor material that extends along a lengthwise direction. As used herein, a “lengthwise direction” is a horizontal direction along with an object extends the most. A “widthwise direction” (W) is a horizontal direction that is perpendicular to each of a fin height (H) and a lengthwise direction.

In various embodiments, the as-formed fins 300 are free standing, i.e., supported only by the substrate. For instance, the handle portion 110 and the insulator layer 120 can collectively function as a substrate on which the plurality of semiconductor fins 300 are disposed. Each fin has a height (H) that may range from 10 nm to 100 nm and a width (W) that may range from 4 nm to 30 nm. Other heights and widths that are less than or greater than the ranges mentioned can also be used. The fins 300 may have an aspect ratio (H/W) ranging from 1 to 5, e.g., 1, 1.5, 2, 3, 4 or 5, including ranges between any of the foregoing values. Plural fins may have identical or substantially identical dimensions, i.e., height and/or width. As used herein, substantially identical dimensions vary by less than 10%, e.g., less than 5%, 2% or 1%.

In structures comprising plural fins, i.e., a fin array, each fin may be spaced apart from its nearest neighbor by a periodicity or pitch (d) of 15 nm to 100 nm, e.g., 15, 20, 25, 30, 40, 50, 75 or 100 nm, including ranges between any of the foregoing values. Such plural fins are typically oriented parallel to each other and perpendicular to the library logic flow of a circuit.

In various embodiments, each of a plurality of semiconductor fins 300 extends along a lengthwise direction with a substantially rectangular vertical cross-sectional shape. As used herein, a “substantially rectangular shape” is a shape that differs from a rectangular shape only due to atomic level roughness that does not exceed 2 nm. The substantially rectangular vertical cross-sectional shape is a shape within a plane including a vertical direction and a widthwise direction. The substantially rectangular vertical cross-sectional shape adjoins a horizontal interface parallel with a top surface of the insulator layer 120. In certain embodiments, each fin 300 has a bottom surface that is contiguous with an upper surface of isolation layer 120.

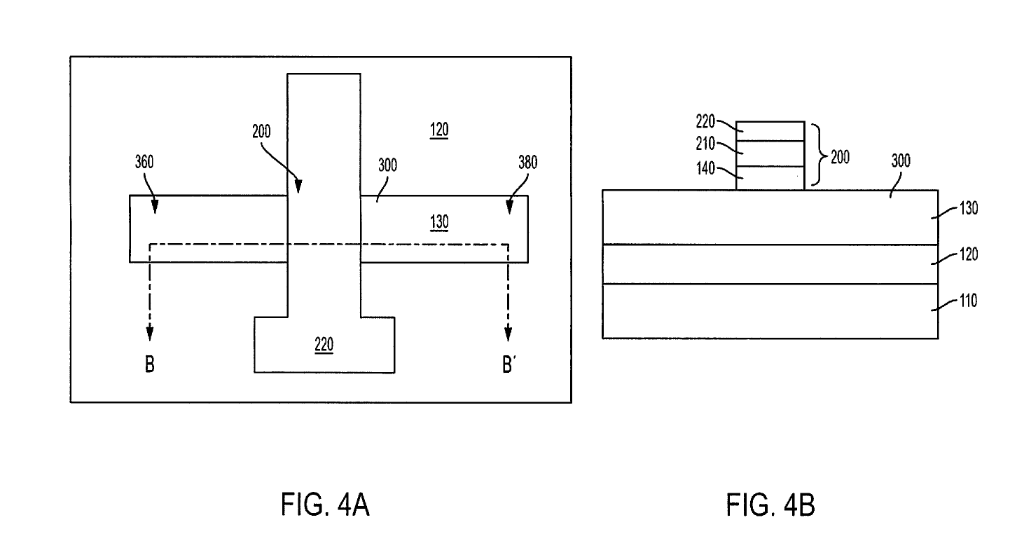

Referring next to FIGS. 4A and 4B, the layer of photoresist 150 may be removed and a gate structure formed over a portion of the fins 300. The gate structure may be a sacrificial gate structure, which is removed later in the manufacturing process, but which may be used as a mask to direct the ion implantation of dopants into the fins. According to various embodiments, one or more layers are deposited over fins 300 and dielectric layer 140, and then patterned and etched to form a sacrificial gate 200. In the illustrated embodiment, dielectric layer 140 is also patterned and etched such that a remaining portion of the dielectric layer 140 underlies the sacrificial gate.

Sacrificial gate 200 may include a dielectric layer 220 such as a silicon dioxide layer and a polysilicon or amorphous silicon layer 210 beneath the dielectric layer 220 and disposed over the dielectric layer 140. Sacrificial gate 200 may have a thickness ranging from 25 to 100 nm, and a width ranging from 5 to 50 nm. The sacrificial gate 200 may be disposed directly over dielectric layer 140 or, in alternate embodiments, dielectric layer 140 may be removed prior to forming the sacrificial gate directly over fin 300.

In various embodiments, reactive ion etching (RIE) can be used to pattern the sacrificial gate structure. In other embodiments, wet etching can be used. In still further embodiments, a combination of dry etching and wet etching can be used. A top view showing an example sacrificial gate structure 200 traversing fin 300 is illustrated in FIG. 4A. A corresponding cross-sectional view taken along line B-B in FIG. 4A is shown in FIG. 4B. The sacrificial gate 200 can define, i.e., overlie, a channel region of the semiconductor device.

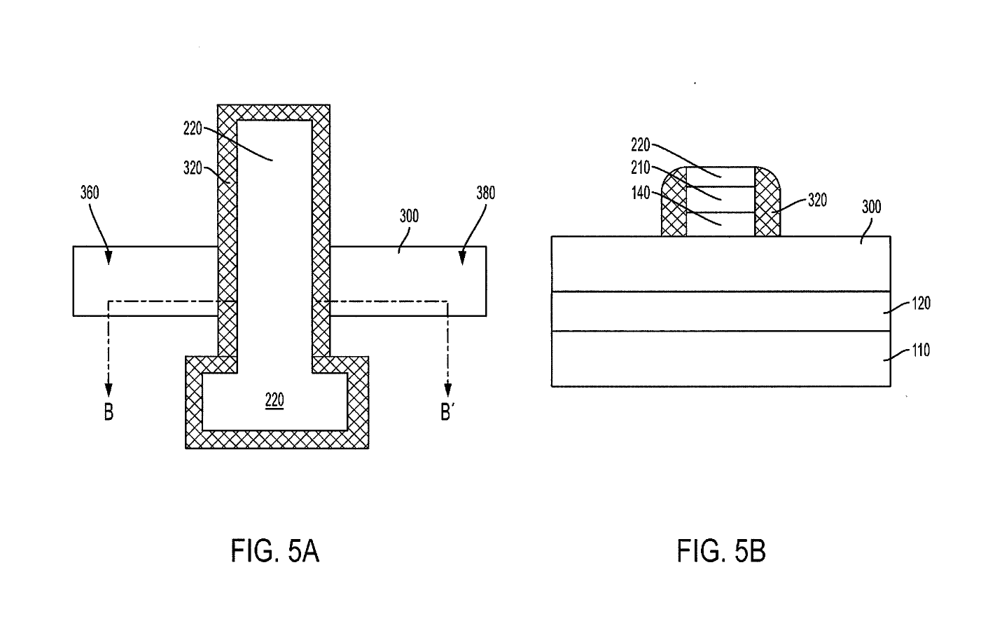

Referring to FIGS. 5A and 5B, a layer of dielectric material may then be deposited and etched to form sidewall spacers 320 over opposing sidewalls of the sacrificial gate structure 200 and dielectric layer 140 and adjacent to source/drain regions 360, 380. Sidewall spacers 320 may comprise silicon dioxide, silicon nitride, or another dielectric material. The sidewall spacers may be deposited by a suitable process such as atomic layer deposition (ALD), chemical vapor deposition (CVD), physical vapor deposition (PVD), thermal oxidation, UV-ozone oxidation, or combinations thereof. In various embodiments, formation of the sidewall spacers 320 includes a conformal deposition process such as chemical vapor deposition (CVD), followed by an anisotropic etch to remove portions of the spacer material(s) from horizontal surfaces. In various embodiments, the width of each spacer 320, as measured at the base of the spacer, may range from 5 nm to 100 nm, although lesser and greater widths can be used. Sidewall spacers 320 may protect the underlying fin during subsequent processing, facilitate doping of source/drain junctions 360, 380, and enable selective removal of the sacrificial gate structure 200, i.e., with respect to the source/drain regions of the fins.

After formation of the sacrificial gate structure 200 and sidewall spacers 320, source and drain regions 360, 380 may be defined in portions of the fins that are not covered by the sacrificial gate structure 200 and sidewall spacers 320. Source and drain regions 360, 380 may be formed using ion implantation, for example. It will be recognized that whenever a region is identified as a source region or a drain region, it is only for convenience as the source and drain regions could be interchanged as understood in the art. Furthermore, the portion of each semiconductor fin 300 that is not converted into a source region or a drain region by doping constitutes a channel region. The channel region of the fins may be substantially un-doped. The channel regions collectively function as a channel of a field effect transistor.

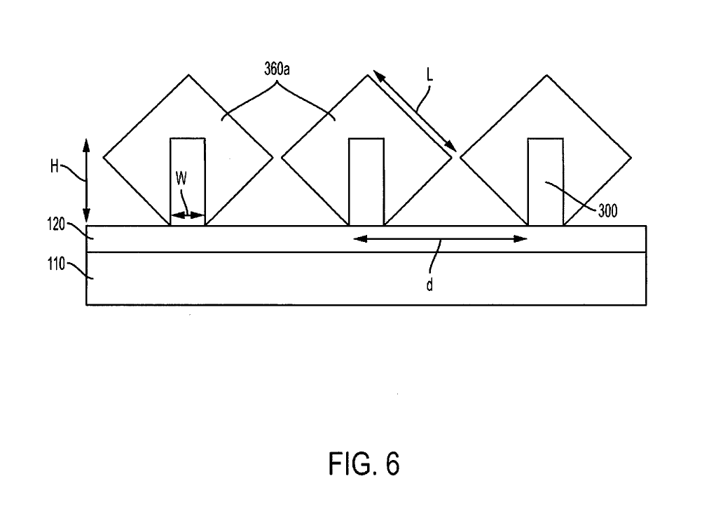

Referring to FIG. 6, source and drain regions 360, 380 may further comprise raised active regions 360a, 380a formed on opposite sides of the sacrificial gate structure 200. As used herein, a “raised active region” refers to a doped semiconductor material portion that protrudes above a topmost surface of an active region of a semiconductor device. An “active region” refers to a semiconductor material portion within a semiconductor device through which charge carriers flow during operation of the device. A “raised region” refers to a material portion that protrudes above a planar surface. As seen in the perspective view of FIG. 1, the plurality of the raised active regions include raised source regions 360a that are formed on a source side of the fins 300 with respect to a gate 400, and raised drain regions 380a that are formed on a drain side of the fins 300 with respect to gate 400.

Raised active regions 360a, 380a may be formed by epitaxial growth directly onto exposed portions of fins 300. In conjunction with various embodiments, the epitaxial growth naturally forms into shaped structures (referred to herein as diamond-shaped or faceted structures). The faceted shape results from the different relative growth rates over different crystallographic orientations. For example, the growth rate of an epitaxial layer on silicon (Si) surfaces having (111) orientations is slower than that on other planes such as (110) or (100) planes. Accordingly, the resultant diamond-shaped structures result from the slowest epitaxial growth rate on the (111) surface.

In the illustrated embodiment, the vertical surfaces of the fins 300 have a (110) crystallographic orientation, while the horizontal top surfaces have a (100) orientation. The faceted top surfaces of the raised active regions have a (111) orientation. The angle between the (111) surface and (110) surface is 35.3°, and the angle between (111) surface and the (100) surface 54.7°. In embodiments, lengths (L) of the facets are substantially the same and can be controlled by the epitaxial growth process conditions, such as growth rate and growth time. Compared to a rectangular shape, the diamond-shaped raised active regions have the advantage of a greater surface area and volume in the active regions, and the flexibility of a multi-layer fin structure (e.g., SiGe diamonds on Si fins).

Example epitaxial growth processes include low energy plasma deposition, liquid phase epitaxy, molecular beam epitaxy, and atmospheric pressure chemical vapor deposition. The terms “epitaxy,” “epitaxial” and/or “epitaxial growth and/or deposition” refer to the growth of a semiconductor material layer on a deposition surface of a semiconductor material, in which the semiconductor material layer being grown assumes the same crystalline habit as the semiconductor material of the deposition surface. For example, in an epitaxial deposition process, chemical reactants provided by source gases are controlled and the system parameters are set so that depositing atoms alight on the deposition surface and remain sufficiently mobile via surface diffusion to orient themselves according to the crystalline orientation of the atoms of the deposition surface. Therefore, an epitaxial semiconductor material has the same crystalline characteristics as the deposition surface on which it is formed. For example, an epitaxial semiconductor material deposited on a (100) crystal surface will take on a (100) orientation.

In addition to, or in lieu of, raised epitaxial source and drain regions, a blanket doping technique may be used to (further) dope source and drain regions 360 and 380 within semiconductor fins 300. Suitable doping techniques may include, but are not limited to, ion implantation, gas phase doping, plasma doping, plasma immersion ion implantation, cluster doping, infusion doping, liquid phase doping, solid phase doping, or any suitable combination of those techniques. In one embodiment, dopants may be implanted by one or more rounds of angled ion implantation. In alternate embodiments, ion implantation to dope source/drain junctions may be performed before or after the formation of the raised active regions. For instance, doping of the source/drain junctions by ion implantation may be used to supplement doping by diffusion from one or more epitaxial layers, or vice versa.

As knows to those skilled in the art, doping changes the electron and hole carrier concentrations of an intrinsic semiconductor at thermal equilibrium. A doped layer or region may be p-type or n-type. As used herein, “p-type” refers to the addition of impurities to an intrinsic semiconductor that creates a deficiency of valence electrons. For silicon, example p-type dopants, i.e., impurities, include but are not limited to, boron, aluminum, gallium, and indium. As used herein, “n-type” refers to the addition of impurities that contribute free electrons to an intrinsic semiconductor. For silicon, example n-type dopants, i.e., impurities, include but are not limited to, antimony, arsenic, and phosphorus. A p-type dopant is used to manufacture a PFET and an n-type dopant is used to manufacture an NFET.

By way of non-limiting example, a doped region, e.g., source or drain region, is doped with arsenic or phosphorus to form an n-type region. In another example, a doped region is doped with boron to form a p-type region. The dopant concentration within the source and drain regions may range from 1×10¹⁹ atoms/cm³ to 5×10²² atoms/cm³, e.g., 1×10¹⁹, 2×10¹⁹, 5×10¹⁹, 1×10²⁰, 2×10²⁰, 5×10²⁰, 1×10²¹, 2×10²¹, 5×10²¹, 1×10²², 2×10²² and 5×10²² atoms/cm³, including ranges between any of the foregoing values.

The implant dose and implant energy may be selected based on the requirements of the device. Each doped region within the semiconductor fins 300 may have the same or different doping concentrations and/or conductivities. The sacrificial gate structure 200 and sidewall spacers 320 can aid in defining the location of the source/drain junctions by shielding portions of the fins 300, e.g., portions within the channel region during epitaxial growth and/or implantation.

Activation annealing may be performed to activate the source/drain junctions 360, 380. For instance, a drive-in anneal (e.g., 600° C. to 1400° C.) can be used to diffuse dopant species and generate a desired dopant profile. The dopant profile within the fins 300 may be constant or variable. For example, after annealing, the dopant concentration within the fins may vary laterally, i.e., along a widthwise direction of the fins, with a minimum dopant concentration (e.g., 1×10¹⁹ to <5×10²² atoms/cm³) along a central axis of the fins and a maximum dopant concentration (e.g., >1×10¹⁹ to 5×10²² atoms/cm³) at opposing sidewall surfaces thereof. In further embodiments, the dopant concentration within the fins may vary along a lengthwise direction of the fins.

According to various embodiments, prior to a dopant-activating anneal, a dopant diffusion-inhibiting species such as carbon or nitrogen is implanted into the source and drain regions of the fins. The dopant diffusion-inhibiting species is implanted to a depth effective to hinder diffusion of the dopant species within the source and drain regions of the fins (e.g., during an activation anneal). In particular embodiments, the dopant diffusion-inhibiting species is not implanted into the channel region of the fins.

As will be appreciated, the diffusion (e.g., thermal diffusion) of one or more dopants within the fins can be modified by the diffusion-inhibiting species, which when incorporated into the fins prior to the dopant-activating anneal can, for example, impede or hinder dopant diffusion and create a large concentration gradient of the dopant, particularly at the respective junctions between the source region and the channel region, and the drain region and the channel region.

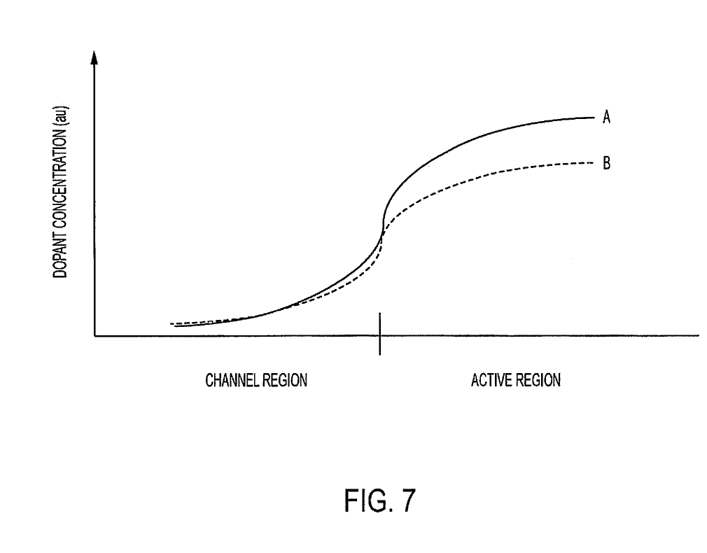

The ability to form an abrupt junction enables a greater overall dopant concentration within the fins while mitigating dopant punch through and a concomitant degradation of short channel effects. This relationship is illustrated schematically in FIG. 7, which is a plot of dopant concentration versus fin position for a p-type or n-type dopant such as boron or antimony. A representative dopant profile showing the effect of carbon doping is shown as Curve A, while a comparative dopant profile for a fin un-doped by carbon is shown as Curve B. The profile represented by Curve A has a higher overall concentration of dopant and a more abrupt concentration gradient at the interface between the channel region and the active region of the fin than the profile represented by Curve B.

The diffusion-inhibiting species may be implanted at a dose ranging from 1×10¹⁴ atoms/cm² to 1×10¹⁷ atoms/cm², e.g., 1×10¹⁴, 2×10¹⁴, 5×10¹⁴, 1×10¹⁵, 2×10¹⁵, 5×10¹⁵, 1×10¹⁶, 2×10¹⁶, 5×10¹⁶ or 1×10¹⁷ atoms/cm², including ranges between any of the foregoing values, at an implantation energy of 2 keV to 10 keV, e.g., 5 keV. The implant angle is generally a small angle with respect to a normal of the substrate, i.e., 5 to 15 degrees into the top surfaces as well as the sidewall surfaces of the fins, but may be lesser or greater such as 0 to 45 degrees. Using such an ion implantation condition results in most of the implanted diffusion-inhibiting species being incorporated into the source/drain regions of the fins. Few diffusion-inhibiting species are effectively implanted into the channel region.

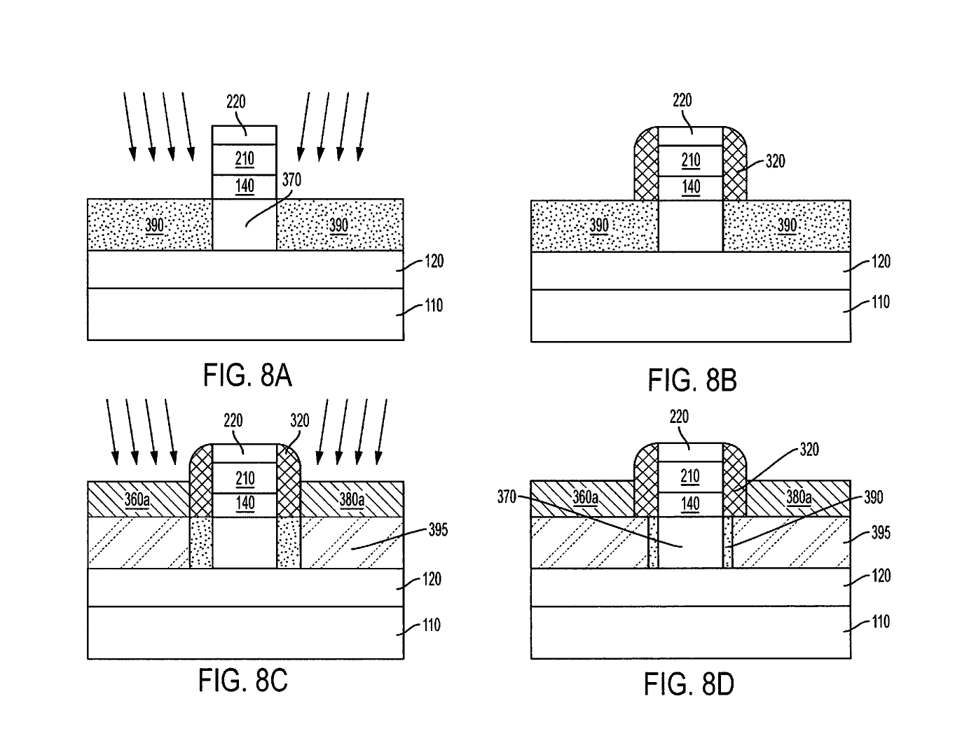

In exemplary embodiments, carbon is implanted as a diffusion-inhibiting species into source/drain regions 360, 380 of the fins in conjunction with a replacement metal gate process prior to the incorporation of p-type or n-type dopants therein. In certain embodiments, as illustrated schematically in FIG. 8A, carbon can be implanted after forming a sacrificial gate but prior to forming sidewalls spacers 320 to form carbon-implanted regions 390. In such case, using the sacrificial gate 200 as an implantation mask, the diffusion-inhibiting species can be implanted into fin 300 adjacent to the channel region 370. In certain embodiments, the diffusion-inhibiting species (e.g., carbon or a carbon-containing compound) can be implanted throughout respective source and drain regions 360, 380. Thus, after forming sidewall spacers 320, as shown in FIG. 8B, the previously-implanted carbon will underlie the sidewall spacers 320. Referring to FIG. 8C, raised active regions 360a, 380a can be formed over source/drain regions. The carbon-containing source/drain regions can then be implanted with a p-type or n-type dopant to form doped regions 395. FIG. 8D shows the structure of FIG. 8C after an activation anneal, where the implanted carbon has diffused into channel region 370 ahead of doped regions 395.

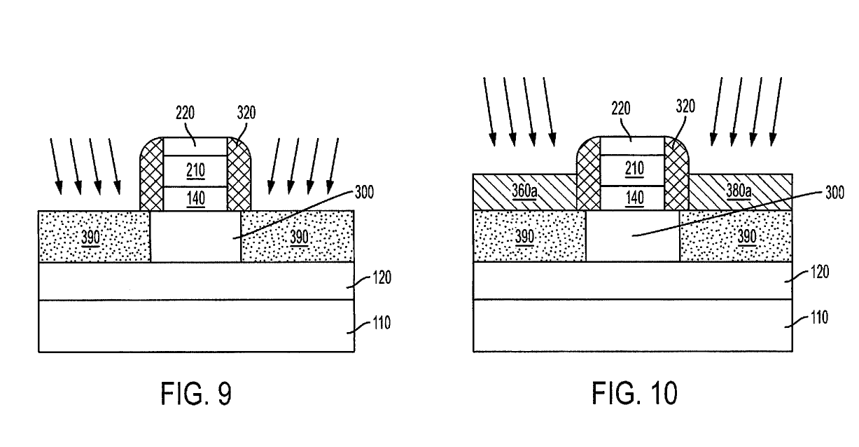

According to further embodiments, referring to FIG. 9, a diffusion-inhibiting species is implanted into the fins after formation of sidewall spacers 320 but prior to doping of source and drain regions 360, 380, i.e., prior to the incorporation of other dopants into the fins such as by implantation or diffusion from epitaxy. In such case, using the sacrificial gate and sidewalls spacers as an implantation mask, the diffusion-inhibiting species can be implanted within the source and drain regions, yet displaced laterally from the channel region of the fin. P-type or n-type dopants can then be implanted into the carbon-implanted regions of the fins. In various embodiments, a diffusion-inhibiting species is implanted prior to forming raised active regions 360a, 380a.

According to still further embodiments, referring to FIG. 10, a diffusion-inhibiting species is implanted into the fins after formation of source and drain regions 360, 380, i.e., after implantation of other dopants into the fins or formation of raised active regions 360a, 380a. In such case, the dopant diffusion-inhibiting species may be implanted deeper than the dopant implant, e.g., at a higher implantation energy, such that the as-implanted carbon resides in front of the dopant diffusion front and during a dopant-activating anneal retards diffusion of the dopant within source/drain junctions 360, 380.

Without wishing to be bound by theory, the implantation of carbon or nitrogen or another diffusion-inhibiting species may induce damage to the crystalline structure of the semiconductor fins, including the creation of locally-strained and/or amorphous regions. The subsequent anneal of implanted dopants such as boron, phosphorus, arsenic, or indium can actively diffuse the dopant ions and recrystallize the amorphous regions. In such a manner, the diffusion-inhibiting species can impede dopant segregation within the fins.

A typical tool for ion implantation includes a source of ions, a system for ion extraction, a system for ion transport, a system for mass analysis, and a substrate processing device. The ion source generates ions of a desired atomic or molecular species. The ions are extracted from the source by an extraction system, which typically includes a plurality of electrodes that energize and direct the flow of ions from the source. A mass analysis system separates the desired ions from byproducts of the ion source. The mass analysis system typically includes a magnetic dipole performing mass dispersion of the extracted ion beam. A vacuum system containing an optical sequence of focusing devices is used to transport an ion beam to the substrate processing system where a workpiece such as a semiconductor wafer is implanted with the atomic or molecular species or ionic fragments thereof.

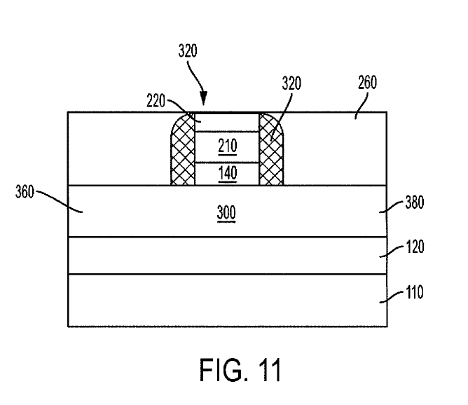

Referring to FIG. 11, after forming source/drain junctions, and performing an activation anneal, a dielectric layer 260 is formed over exposed portions of the source region 360, the drain region 380 and the isolation layer 120. Following the deposition of the dielectric layer 260, a planarizing process such as, for example, chemical mechanical polishing (CMP) may be performed to expose the sacrificial gate structure 200 and the spacers 320. Chemical mechanical polishing (CMP) is a material removal process that uses both chemical reactions and mechanical forces to remove material and planarize a surface.

A selective etch is used to remove the sacrificial gate 200 and, if present, dielectric layer 140, to expose the top surface and sidewalls of the fins within a gate cavity within the channel region 370. The formation of a gate dielectric, a gate electrode, and a gate cap can then be effected, for example, by deposition of a stack of a gate dielectric layer, one or more conductive layer and gate cap layer, and by subsequent patterning of the layers. Patterning can be performed using a combination of lithographic methods and at least one anisotropic etch that is selective to the semiconductor material used to form semiconductor fins.

Referring again to FIG. 1, a gate stack is formed over exposed surfaces of the fins 300 within the channel region 370. The gate stack 400 comprises a gate dielectric layer 410, one or more conductive layers 430, including a work function metal layer and a gate conductor, and a gate cap 440.

The gate dielectric layer 410 may be formed by conformally depositing a dielectric material by CVD or atomic layer deposition (ALD) over the sidewalls and the bottom surface of the gate cavity. Gate dielectric layer 410 may comprise silicon dioxide, silicon nitride, silicon oxynitride, a high-k dielectric, or other suitable material. As used herein, a high-k material has a dielectric constant greater than that of silicon dioxide. A high-k dielectric may include a binary or ternary compound such as hafnium oxide (HfO₂). Further exemplary high-k dielectrics include, but are not limited to, ZrO₂, La₂O₃, Al₂O₃, TiO₂, SrTiO₃, BaTiO₃, LaAlO₃, Y₂O₃, HfOₓN_{y}, HfSiOₓN_{y}, ZrOₓN_{y}, La₂OₓN_{y}, Al₂OₓN_{y}, TiOₓN_{V}, SrTiOₓN_{y}, LaAlOₓN_{y}, Y₂OₓN_{y}, SiOₓN_{y}, SiNₓ, a silicate thereof, and an alloy thereof. Each value of x may independently vary from 0.5 to 3, and each value of y may independently vary from 0 to 2. The gate dielectric thickness may range from 1 nm to 10 nm, e.g., 1, 2, 4, 6, 8 or 10 nm, including ranges between any of the foregoing.

Subsequently, a work function metal layer is conformally deposited over the gate dielectric layer 410. The work function metal layer may include TiAlC, TaAlC, TiAl, Ti, or Al. The work function of the work function metal layer may range from 4.1 eV to 4.3 eV. The work function metal layer may be formed by a suitable deposition process such as, for example, CVD, PVD or ALD. The work function metal layer that is formed may have a thickness ranging from 1 nm to 10 nm, although lesser and greater thicknesses can also be employed.

A gate conductor layer is then formed over the work function metal layer to fill a remaining volume of the gate cavity. The gate conductor layer may include any conductive material including, for example, may include a conductive material such as polysilicon, silicon-germanium, a conductive metal such as Al, W, Cu, Ti, Ta, W, Pt, Ag, Au, Ru, Ir, Rh and Re, alloys of conductive metals, e.g., Al—Cu, silicides of a conductive metal, e.g., W silicide, and Pt silicide, or other conductive metal compounds such as TiN, TiC, TiSiN, TiTaN, TaN, TaAlN, TaSiN, TaRuN, WSiN, NiSi, CoSi, as well as combinations thereof. The gate conductor layer may be formed by a conventional deposition process such as, for example, ALD, CVD, metalorganic chemical vapor deposition (MOCVD), molecular beam epitaxy (MBE), PVD, sputtering, plating, evaporation, ion beam deposition, electron beam deposition, laser assisted deposition, or chemical solution deposition. Chemical mechanical polishing may be used to remove overburden material and define the gate stack 400. For clarity, the work function metal and the gate conductor are shown collectively as conductive layer 430, and dielectric layer 260 is omitted from the perspective view of FIG. 1.

A further contact-level dielectric layer (not shown) may be deposited over exposed surfaces of the structure of FIG. 11. The contact-level dielectric layer may be self-planarizing, or the top surface of the dielectric layer can be planarized, for example, by chemical mechanical polishing (CMP).

Source, drain and gate contacts may be formed by etching contact vias through the dielectric layers and depositing a suitable conductor into the vias using a deposition process such as ALD, CVD, metalorganic chemical vapor deposition (MOCVD), molecular beam epitaxy (MBE), PVD, sputtering, plating, evaporation, ion beam deposition, electron beam deposition, laser assisted deposition, or chemical solution deposition.

Source and drain contacts may comprise a conductive metal such as Al, W, Cu, Ti, Ta, W, Pt, Ag, Au, Ru, Ir, Rh and Re, alloys of conductive metals, e.g., Al—Cu, silicides of a conductive metal, e.g., W silicide, and Pt silicide, or other conductive metal compounds such as TiN, TiC, TiSiN, TiTaN, TaN, TaAlN, TaSiN, TaRuN, WSiN, NiSi, CoSi, as well as combinations thereof.

Thus, in various embodiments, the semiconductor device is fabricated using a gate last (i.e., replacement metal gate) process. In a gate last process, as described above, a sacrificial gate structure is formed followed by CMOS processing. Thereafter, the sacrificial gate structure is removed followed by the formation of a replacement gate structure.

Disclosed are methods of inhibiting dopant diffusion within source/drain regions of a FinFET device. The FinFET device may be included in a microprocessor, memory cell, or other type of integrated circuit device. Certain embodiments include forming a barrier by localized implantation of a diffusion-inhibiting species such as carbon, which creates a local stress field that inhibits or retards the diffusion of dopant species across the barrier.

As used herein, the singular forms “a,” “an” and “the” include plural referents unless the context clearly dictates otherwise. Thus, for example, reference to a “fin” includes examples having two or more such “fins” unless the context clearly indicates otherwise.

Unless otherwise expressly stated, it is in no way intended that any method set forth herein be construed as requiring that its steps be performed in a specific order. Accordingly, where a method claim does not actually recite an order to be followed by its steps or it is not otherwise specifically stated in the claims or descriptions that the steps are to be limited to a specific order, it is no way intended that any particular order be inferred. Any recited single or multiple feature or aspect in any one claim can be combined or permuted with any other recited feature or aspect in any other claim or claims.

It will be understood that when an element such as a layer, region or substrate is referred to as being formed on, deposited on, or disposed “on” or “over” another element, it can be directly on the other element or intervening elements may also be present. In contrast, when an element is referred to as being “directly on” or “directly over” another element, no intervening elements are present.

While various features, elements or steps of particular embodiments may be disclosed using the transitional phrase “comprising,” it is to be understood that alternative embodiments, including those that may be described using the transitional phrases “consisting” or “consisting essentially of,” are implied. Thus, for example, implied alternative embodiments to a dielectric layer that comprises silicon nitride include embodiments where a dielectric layer consists essentially of silicon nitride and embodiments where a dielectric layer consists of silicon nitride.

It will be apparent to those skilled in the art that various modifications and variations can be made to the present invention without departing from the spirit and scope of the invention. Since modifications, combinations, sub-combinations and variations of the disclosed embodiments incorporating the spirit and substance of the invention may occur to persons skilled in the art, the invention should be construed to include everything within the scope of the appended claims and their equivalents.

1. A method of forming a fin field effect transistor (FinFET) device, comprising:
forming a plurality of fins on a semiconductor substrate;
forming a sacrificial gate stack on portions of the fins to define source/drain regions not covered by the sacrificial gate stack;
implanting a diffusion-inhibiting species into the source/drain regions, wherein the diffusion-inhibiting species is carbon or nitrogen; and
forming source/drain junctions by incorporating a dopant into the source/drain regions.

2. The method of claim 1, wherein forming the sacrificial gate stack comprises:
forming a dielectric layer directly on the portions of the fins; and
forming a semiconductor layer directly on the dielectric layer.

3. The method of claim 1, wherein the diffusion-inhibiting species is implanted at a dose of 1×10¹⁴ atoms/cm² to 1×10¹⁷ atoms/cm².

4. The method of claim 1, wherein the diffusion-inhibiting species is implanted at an angle of 0 to 45 degrees with respect to a normal direction from the semiconductor substrate.

5. The method of claim 1, wherein forming the source/drain junctions comprises implanting the dopant into the source/drain regions after implanting the diffusion-inhibiting species.

6. The method of claim 1, wherein forming the source/drain junctions comprises implanting the dopant into the source/drain regions before implanting the diffusion-inhibiting species.

7. The method of claim 1, wherein forming the source/drain junctions comprises forming epitaxial raised active regions over the source/drain regions.

8. The method of claim 1, wherein the dopant has a concentration of 1×10¹⁹ atoms/cm³ to 5×10²² atoms/cm³.

9. The method of claim 1, further comprising activating the dopant by heating the semiconductor substrate to a temperature of 600° C. to 1400° C.

10. The method of claim 1, further comprising forming at least one spacer on sidewalls of the sacrificial gate stack and adjacent to the source/drain regions of the fins.

11. A method of forming a fin field effect transistor (FinFET) device, comprising:
forming a plurality of fins on a semiconductor substrate;
forming a sacrificial gate stack on portions of the fins to define source/drain regions not covered by the sacrificial gate stack;
implanting a diffusion-inhibiting species selected from the group consisting of carbon and nitrogen into the source/drain regions;
forming at least one spacer on sidewalls of the sacrificial gate stack and adjacent to the source/drain regions of the fins; and
forming source/drain junctions by incorporating a dopant into the source/drain regions, wherein the diffusion-inhibiting species is implanted before forming the at least one spacer and the dopant is incorporated into the source/drain regions after forming the at least one spacer.

12. The method of claim 1, further comprising:
forming a dielectric layer on the substrate;
removing the sacrificial gate stack to expose the portions of the fins; and
forming a gate stack on the exposed portions of the fins.

13. A fin field effect transistor (FinFET) device, comprising:
a plurality of fins on a semiconductor substrate;
a gate stack overlying portions of the fins; and
at least one spacer disposed on a sidewall the gate stack and adjacent to source/drain regions of the fins, wherein the fins comprise a diffusion-inhibiting species selected from the group consisting of carbon and nitrogen beneath the at least one spacer.

14. The fin field effect transistor (FinFET) device of claim 13, wherein the diffusion-inhibiting species is incorporated throughout the source/drain regions of the fins.

15. The fin field effect transistor (FinFET) device of claim 13, wherein the diffusion-inhibiting species is incorporated adjacent to a channel region of the fins.

16. The fin field effect transistor (FinFET) device of claim 13, wherein the source/drain regions further comprise a dopant.

17. The fin field effect transistor (FinFET) device of claim 15, wherein the dopant concentration is from 1×10¹⁹ atoms/cm³ to 5×10²² atoms/cm³.

18. The fin field effect transistor (FinFET) device of claim 13, wherein the fins comprise a channel region located beneath the gate stack and the channel region of the fins is substantially free of the diffusion-inhibiting species.
